(19) United States
(12) Patent Application Publication
(10) Pub. No.: US 2011/0065280 A1
(43) Pub. Date: Mar. 17, 2011

(54) MASK PATTERN FORMING METHOD AND SEMICONDUCTOR DEVICE MANUFACTURING METHOD

(75) Inventors: Shigeru Nakajima, Oshu City (JP); Kazuhide Hasebe, Nirasaki City (JP); Hidetami Yaegashi, Nirasaki City (JP); Eiichi Nishimura, Nirasaki City (JP)

(73) Assignee: TOKYO ELECTRON LIMITED, Tokyo (JP)

(21) Appl. No.: 12/852,543

(22) Filed: Aug. 9, 2010

(30) Foreign Application Priority Data
Sep. 16, 2009 (JP) 2009-214952

(51) Int. Cl. H01L 21/306

(52) U.S. Cl. 438/735; 257/E21.215

(57) ABSTRACT

The method includes a film-forming process which forms a carbon film, to isotropically coat a surface of a silicon film pattern in which a first line portion formed of a silicon film that is formed on a target etching film on a substrate is arranged, an etchback process which etches back the carbon film such that the carbon film is removed from an upper portion of the first line portion and remains as a side wall portion of the first line portion, and a silicon film removing process which forms a mask pattern in which the side wall portion is arranged, by removing the first line portion.

### CROSS-REFERENCE TO RELATED PATENT APPLICATIONS

This application claims the benefit of Japanese Patent Application No. 2009-214952 filed on Sep. 16, 2009, in the Japan Patent Office, the disclosure of which is incorporated herein in its entirety by reference.

### BACKGROUND OF THE INVENTION

1. Field of the Invention

The present invention relates to a method of manufacturing a semiconductor device and a method of forming a mask pattern included in the method of manufacturing a semiconductor device.

2. Description of the Related Art

With the high integration of a semiconductor device, the pattern of a wiring or a separation width required in a manufacturing process tends to be fine. The fine pattern (hereinafter, referred to as the “micro pattern”) is formed by forming a resist pattern using photolithography technology and etching various thin films thereunder using the resist pattern as a mask pattern. The photolithography technology is important for forming the mask pattern. The recent scaling down of a semiconductor device even requires a resolution far less than the limitation in the resolution of the photolithography technology.

As a method of forming a fine mask pattern under the limitation of the resolution of the photolithography technology, a so-called double patterning method (a double patterning process) is provided. According to the double patterning method, compared to a case of forming an etching mask by one time patterning, a fine gap is formed by performing two-step patterning of a first mask pattern forming step and a second mask pattern forming step that is performed after the first mask pattern forming step.

Also, a SWP (Side Wall Process) method using a side wall portion formed on both sides of a pattern as a mask is known as a method of forming a mask having a fine pitch than the original resist pattern. According this method, a resist pattern in which a line portion is arranged is formed by forming a photoresist film, a silicon oxide film is formed to isotropically coat a surface of the resist pattern, and etchback is performed so that the silicon oxide film is left only on the side wall portion that coats a side wall of the resist pattern. Thereafter, the pattern of the photoresist film is removed, and thus, the silicon oxide film that is a remaining side wall portion is functioned as a mask pattern (e.g., refer to Japanese Laid-Open Patent Publication No. 2009-16813).

### SUMMARY OF THE INVENTION

However, when the film-forming process for forming the silicon oxide film to coat a surface of the resist pattern is combined to the SWP as described above, the following problems occur.

When the side wall portion constituting a mask pattern is formed to be a side wall of the resist pattern, in the process of trimming the resist pattern, forming the silicon oxide film, or performing etchback on the silicon oxide film, since the tip end of the line portion constituting the resist pattern becomes narrower at its end portion, the side wall portion at both sides of the line portion is bent toward the center of the line portion, thereby forming an asymmetrical shape like a crab claw. When a target etching film is etched using the side wall portion of an asymmetrical shape, a shape forming process, referred to as a nail clean, for processing the shape of only the tip end of the side wall portion to make a symmetrical shape, needs to be added in advance. Also, when the side wall portion still has the asymmetrical shape in spite of the shape forming process, processing accuracy may be deteriorated when etching a film under the side wall portion.

Furthermore, when the silicon oxide film is used as the side wall portion, since the ratio (the selection ratio) of an etching rate of the target etching film to the silicon oxide film cannot be made high, the film thickness of the silicon oxide film needs to be increased. In this case, since the width size of the side wall portion also increases, the line width and space width of the mask pattern formed of the side wall portion may be difficult to be decreased.

To solve the above and/or other problems, the present invention provides a method of forming a mask pattern which may increase symmetry of the shape of the side wall portion and improve processing accuracy when etching a target etching film, in the SWP.

In an embodiment of the present invention, a method of forming a mask pattern includes a film-forming process which forms a carbon film, to isotropically coat a surface of a silicon film pattern in which a first line portion formed of a silicon film that is formed on a target etching film on a substrate is arranged, an etchback process which etches back the carbon film such that the carbon film is removed from an upper portion of the first line portion and remains as a side wall portion of the first line portion, and a silicon film removing process which forms a mask pattern in which the side wall portion is arranged, by removing the first line portion.

In an another embodiment of the present invention, a method of manufacturing a semiconductor device includes a target etching film pattern forming process which forms a pattern formed of the target etching film, by using the mask pattern formed by performing the method of forming a mask pattern.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart for explaining the sequence of processes of a method of manufacturing a semiconductor device including a method of forming a mask pattern according to an embodiment of the present invention;

FIG. 2A is a view for explaining the method of manufacturing a semiconductor device including a method of forming a mask pattern according to an embodiment of the present invention, and is a part of a sectional view schematically showing the structure of a semiconductor substrate in each process;

FIG. 2B is a view for explaining the method of manufacturing a semiconductor device including a method of forming a mask pattern according to an embodiment of the present invention, and is another part of a sectional view schematically showing the structure of a semiconductor substrate in each process;

FIG. 2C is a view for explaining the method of manufacturing a semiconductor device including a method of forming a mask pattern according to an embodiment of the present invention, and is still another part of a sectional view schematically showing the structure of a semiconductor substrate in each process;

FIG. 3 is a vertical sectional view schematically showing the structure of a film-forming apparatus used in the method of manufacturing a semiconductor device including a method of forming a mask pattern according to an embodiment of the present invention;

FIG. 4 is a horizontal sectional view schematically showing the structure of the film-forming apparatus used in the method of manufacturing a semiconductor device including a method of forming a mask pattern according to an embodiment of the present invention;

FIG. 5 is a timing chart showing the timing of supply of a gas when a target etching film is formed, and explaining a method of forming a mask pattern according to an embodiment of the present invention;

FIG. 6 is images of patterns after the film-forming process is performed according to an embodiment of the present invention, and views for explaining the images;

FIG. 7 is images of patterns after the etchback process is performed according to an embodiment of the present invention, and views for explaining the images;

FIG. 8 is images of patterns after the target etching film etching process and the carbon film removing process are additionally performed, after the silicon film removing process is performed according to an embodiment of the present invention, and views for explaining the images; and

FIG. 9 is images of patterns after the silicon oxide film is formed to coat the surface of a resist pattern in a comparative example, and views for explaining the images.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

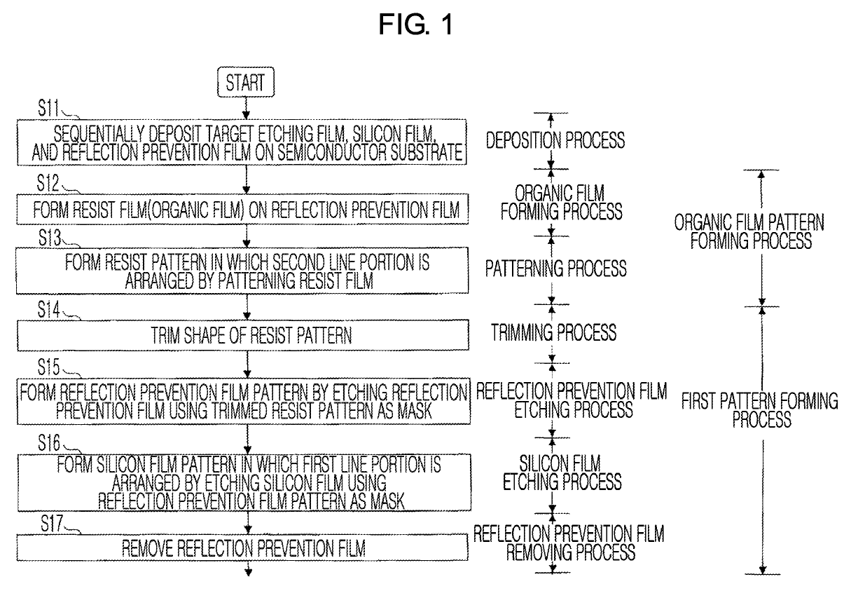

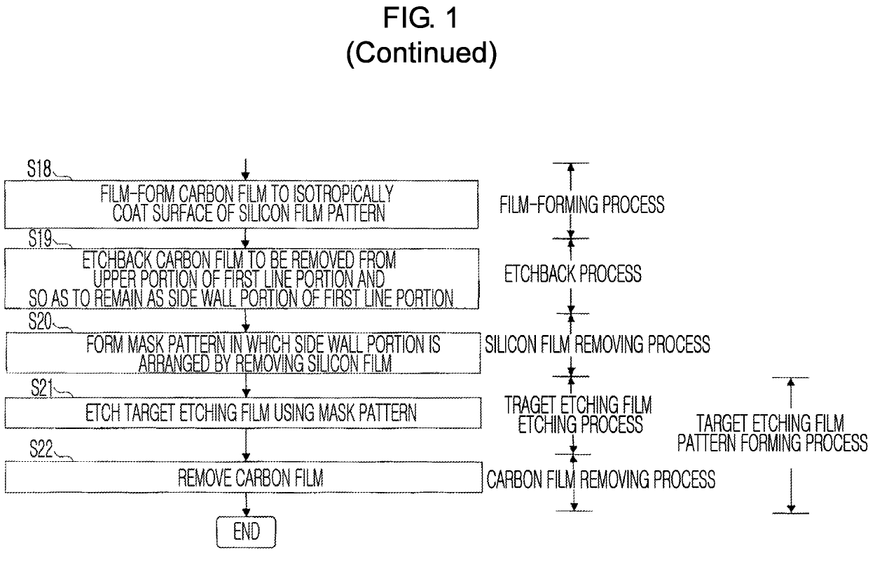

Referring to FIGS. 1-4, a method of manufacturing a semiconductor device including a method of forming a mask pattern according to an embodiment of the present invention will be described.

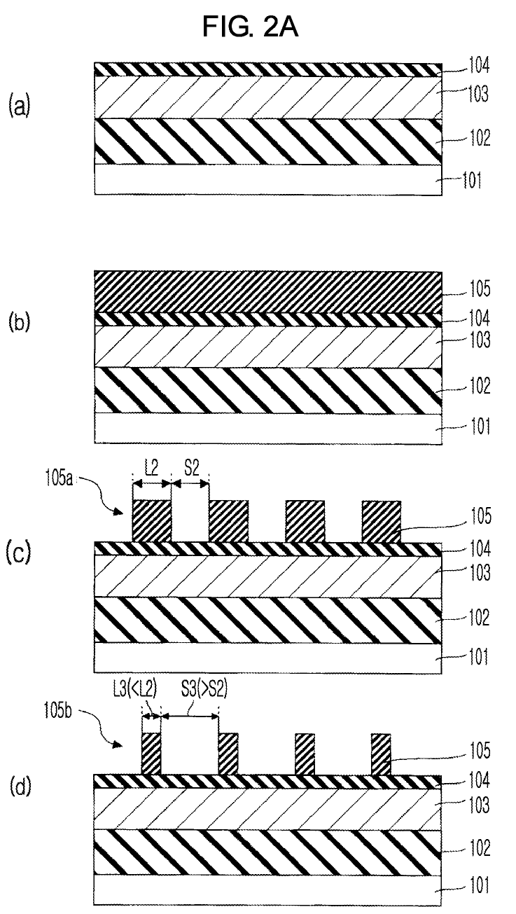

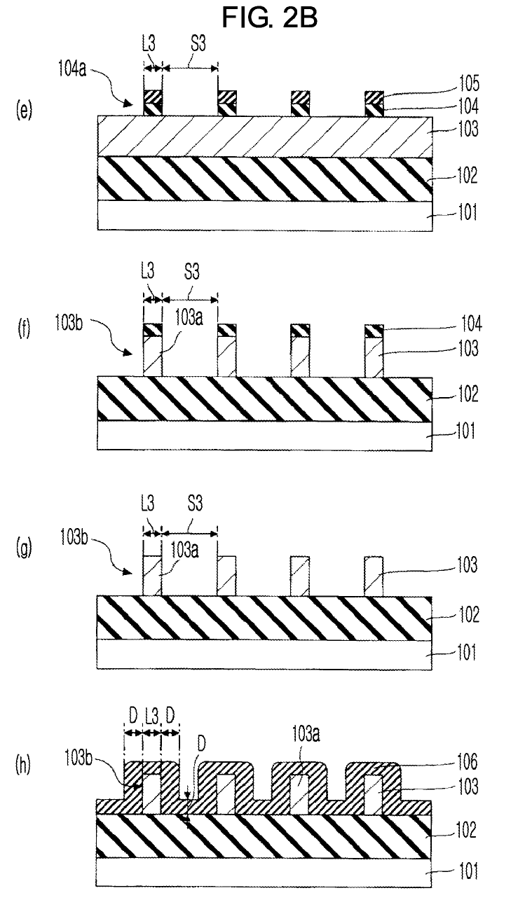

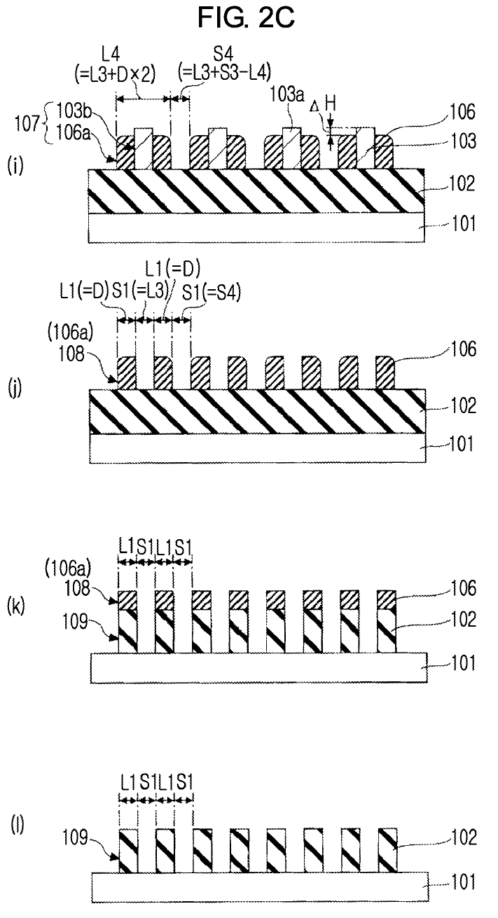

First, referring to FIGS. 1-2C, a method of manufacturing a semiconductor device including a method of forming a mask pattern according to an embodiment of the present invention will be described.

FIG. 1 is a flowchart for explaining the sequence of processes of a method of manufacturing a semiconductor device including a method of forming a mask pattern according to an embodiment of the present invention. FIG. 2A-2C are views for explaining the method of manufacturing a semiconductor device including a method of forming a mask pattern according to an embodiment of the present invention, and are sectional views schematically showing the structure of a semiconductor substrate in each process. Also, the structure of a semiconductor substrate after each process of Step S11 through Step S22 is performed corresponds to the structure illustrated in sectional views of FIGS. 2A(a)-2C(l), respectively.

The method of manufacturing a semiconductor device including a method of forming a mask pattern according to an embodiment of the present invention includes, as shown in FIG. 1, a deposition process (Step S11), an organic film pattern forming process (Step S12 and Step S13), a first pattern forming process (Step S14 through Step S17), a film-forming process (Step S18), an etchback process (Step S19), a silicon film removing process (Step S20), a target etching film etching process (Step S21), and a carbon film removing process (Step S22).

The organic film pattern forming process (Step S12 and Step S13) includes an organic film forming process (Step S12) and a patterning process (Step S13). The first pattern forming process (Step S14 through Step S17) includes a trimming process (Step S14), a reflection prevention film etching process (Step S15), a silicon film etching process (Step S16), and a reflection prevention film removing process (Step S17).

Also, the processes from the deposition process (Step S11) to the silicon film removing process (Step S20) correspond to the method of forming a mask pattern according to an embodiment of the present invention.

In Step S11, a target etching film 102, a silicon film 103, and a reflection prevention film 104 are sequentially deposited on a semiconductor substrate 101. FIG. 2A(a) is a cross-sectional view showing the structure of a semiconductor substrate after Step S11 is performed.

In Step S11, as shown in FIG. 2A(a), the target etching film 102, the silicon film 103, and the reflection prevention film 104 are sequentially deposited from the bottom on the semiconductor substrate 101. The target etching film 102 functions as a mask when a pattern is formed and then various processing processes are performed on the semiconductor substrate 101. The silicon film 103 exists as as to form a mask pattern formed of a carbon film as a side wall portion of a first line portion after forming a silicon film pattern where the first line portion is arranged. The reflection prevention film 104 is a bottom anti-reflecting coating (BARC) when photolithography with respect to a photoresist film 105 formed on the reflection prevention film 104 is performed.

Also, the semiconductor substrate 101 is defined to include a structure in which a conductive film corresponding to a semiconductor device or an integrated circuit pattern formed in the semiconductor substrate or on the semiconductor substrate, not merely to indicate a semiconductor, for example, a silicon substrate.

Although the material of the target etching film 102 is not particularly limited, for example, a film including nitride silicon (SiN) may be used. Also, the thickness of the target etching film 102 is not particularly limited and may be, for example, 10-1000 nm.

As the silicon film 103, for example, a film including amorphous silicon or polysilicon may be used. Also, the thickness of the silicon film 103 is not particularly limited and may be, for example, 50-1000 nm.

The material of the reflection prevention film 104 is not particularly limited. For example, an organic based material in a large range including a crosslinking agent or thermosetting resin film-formed by spin-on may be used as the material of the reflection prevention film 104. Also, the thickness of the reflection prevention film 104 is not particularly limited and may be, for example, 20-150 nm.

In Step S12, the photoresist film 105 is formed on the reflection prevention film 104. FIG. 2A(b) is a cross-sectional view showing the structure of the semiconductor substrate after Step S12 is performed.

The material of the photoresist film 105 may be, for example, ArF resist. Also, the thickness of the photoresist film 105 is not particularly limited and may be, for example, 50-200 nm.

Next, the patterning process of Step S13 is performed. In Step S13, a resist pattern 105a formed of the photoresist film 105 is formed by exposing and developing the film-formed photoresist film 105. Also, FIG. 2A(c) is a cross-sectional view showing the structure of a micro pattern after Step S13 is performed.

As shown in FIG. 2A(c), the resist pattern 105a which is formed of the photoresist film 105 and in which a second line portion having a line width L2 and a space width S2 is arranged is formed. The resist pattern 105a functions as a mask in a process of etching the reflection prevention film 104. The line width L2 and the space width S2 of the resist pattern 105a are particularly limited and both may be set to, for example, 40 nm.

Next, the trimming process of Step S14 is performed. In Step S14, the resist pattern 105a formed of the photoresist film 105 is trimmed, and thus, a resist pattern 105b formed of the photoresist film 105 is formed. Also, FIG. 2A(d) is a cross-sectional view showing the structure of the semiconductor substrate after Step S14 is performed.

Also, the trimming process corresponds to shaping process in a shape processing process and is referred to as a sliming process.

The method of trimming process is not particularly limited and an example of a trimming process condition is a condition of a temperature from the room temperature to 100° C. in an atmosphere including oxygen radical or ozone gas. Also, as shown in FIGS. 2A(c) and 2A(d), since the line width L3 of the resist pattern 105b formed by the trimming process becomes narrower than the line width L2 of the resist pattern 105a before performing the trimming process, the relationship in the size between the line width L3 and the space width S3 of the resist pattern 105b, and the line width L2 and the space width S2 of the resist pattern 105a is L3<L2 and S3<S2. The values of L3 and S3 are not particularly limited and, for example, L3 and S3 may be 20 nm and 60 nm, respectively.

Next, the reflection prevention film etching process of Step S15 is performed. In Step S15, the reflection prevention film 104 is etched by using the trimmed resist pattern 105b as a mask, and thus, a reflection prevention film pattern 104a formed of the reflection prevention film 104 and having the line width L3 and the space width S3 is formed. Also, FIG. 2B(e) is a cross-sectional view showing the structure of the semiconductor substrate after Step S15 is performed.

Also, the resist pattern 105b may be left, without being completely removed by the etching, on an upper portion of each line portion of the reflection prevention film pattern 104a.

Next, the silicon film etching process of Step S16 is performed. In Step S16, the silicon film 103 is etched by using the reflection prevention film pattern 104a as a mask, and thus, a silicon film pattern 103b which is formed of the silicon film 103 and in which a first line portion 103a having the line width L3 and the space width S3 is arrayed is formed. Also, FIG. 2B(f) is a cross-sectional view showing the structure of the semiconductor substrate after Step S16 is performed.

Next, the reflection prevention film removing process of Step S17 is performed. In Step S17, the reflection prevention film 104 remaining on the upper portion of each line portion of the silicon film pattern 103b is removed. Also, FIG. 2B(g) is a cross-sectional view showing the structure of the semiconductor substrate after Step S17 is performed.

Next, the film-forming process including a process of Step S18 is performed. In Step S18, a carbon film 106 is formed to isotropically coat the surface of the silicon film pattern 103b. Also, FIG. 2B(h) is a cross-sectional view showing the structure of the semiconductor substrate after Step S18 is performed.

As shown in FIG. 2B(h), the carbon film 106 is formed on the overall surface of the substrate including the place where the silicon film pattern 103b is formed and the place where the silicon film pattern 103b is not formed. At this time, the carbon film 106 is formed to isotropically coat the surface of the first line portion 103a of the silicon film pattern 103b. Thus, the carbon film 106 is formed on the side surface of the first line portion 103a. Assuming that the thickness size of the carbon film 106 is D, the width size of the carbon film 106 coating the side surface of the first line portion 103a is also D. The thickness size D of the carbon film 106 is not particularly limited and may be, for example, 20 nm.

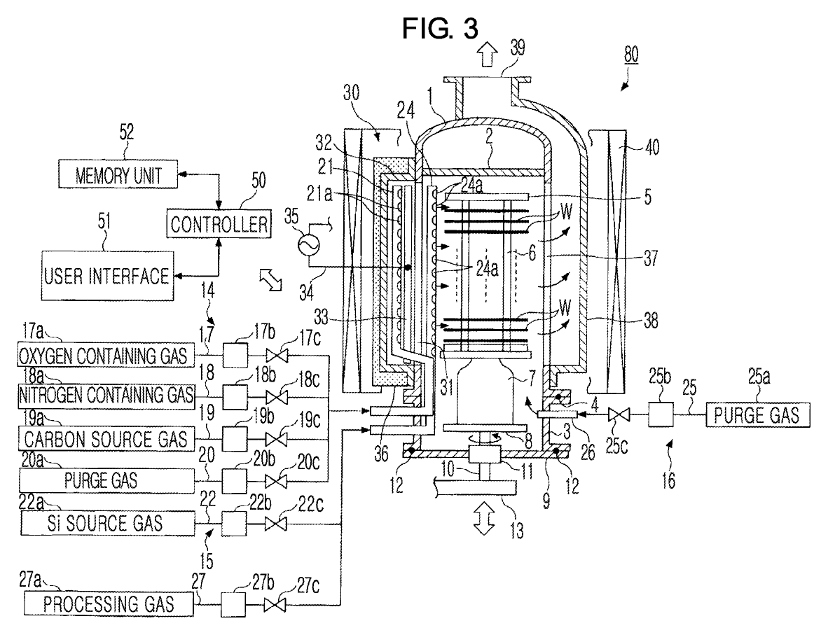

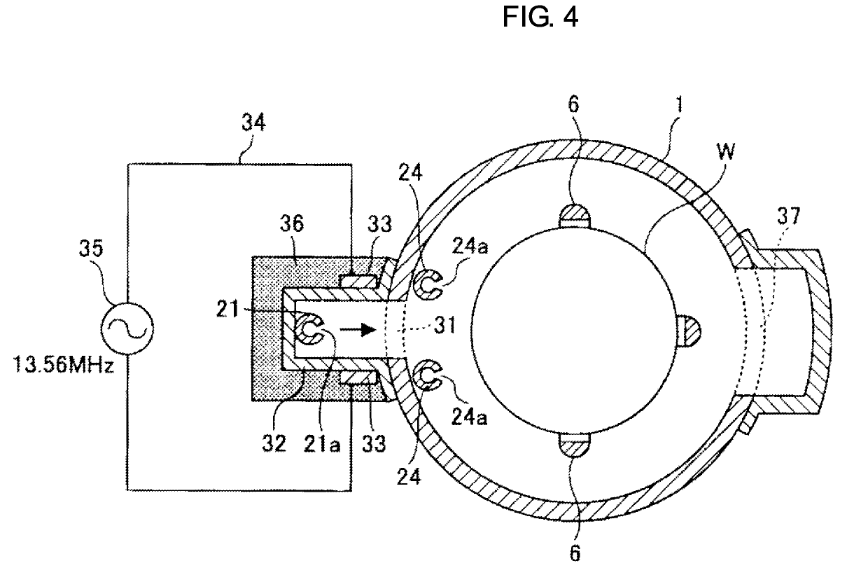

As the carbon film 106, an amorphous carbon film may be formed. Also, a film-forming apparatus performing the film-forming process of an amorphous carbon film will be described later with reference to FIGS. 3 and 4.

Next, the etchback process of Step S19 is performed. In Step S19, the carbon film 106 is removed from the upper portion of the first line portion 103a and simultaneously the carbon film 106 is etched thereby remaining as a side wall portion 106a of the first line portion 103a. Also, FIG. 2C(i) is a cross-sectional view showing the structure of the semiconductor substrate after Step S19 is performed.

As shown in FIG. 2C(i), the carbon film 106 is etched back, the carbon film 106 is removed from the upper portion of the first line portion 103a, and the carbon film 106 is etched back again, so that the carbon film 106 is left as the side wall portion 106a coating the side surface of the first line portion 103a. The etching method for etchback of the carbon film 106 is not particularly limited and may be performed by using a process gas, for example, gas including oxygen such as oxygen gas O₂, or gas including oxygen in which CF based gas such as CF₄, C₄F₈, CHF₃, CH₃F, or CH₂F₂ or Ar gas is added. Since the carbon film 106 is removed from the upper portion of the first line portion 103a and etched away to have only the side wall portion 106a of the silicon film pattern 103b formed of the first line portion 103a left, a pattern 107 formed of the silicon film pattern 103b and the side wall portion 106a is formed. Assuming that the line width of the patter 107 and the space width are L4 and S4, respectively, and when the line width L3 of the resist pattern 105b and the thickness D of the side wall portion 106a are 20 nm and 20 nm, respectively, L4=L3+D×2 and S4=L3+S3−L4, thereby respectively making L4 and S4 60 nm and 20 nm.

Also, in the film-forming process and the etchback process, since the tip end of the first line portion 103a formed of the silicon film 103 becomes narrower toward the end portion thereof, the first line portion 103a has a portion protruding higher than the side wall portion 105a. The height of the protruding portion is set to be LH.

Also, the etchback refers to making the surface of a film retreat in a thickness direction (in a direction perpendicular to the substrate) by etching.

The silicon film removing process of Step S20 is performed. In Step S20, a mask pattern 108 in which the side wall portion 106a is arranged is formed by removing the silicon film 103. Also, FIG. 2C(j) is a cross-sectional view showing the structure of the semiconductor substrate after the silicon film removing process is performed.

As shown in FIG. 2C(j), the mask pattern 108 in which a line width is D and space widths are alternately L3 and S4 is formed. In the present embodiment, by equalizing the line width L3 of the silicon film pattern 103b and the space width S4 of the pattern 107, the space width of the mask pattern 108 becomes S1 that is the same as L3 and S4. Also, the line width that is the same as D is set to be L1 again. As described above, by respectively setting L3, S4, and the thickness size of the carbon film 106 (the width size of the side wall portion 106a) D to be 20 nm, 20 nm, and 20 nm, the mask pattern 108 having the line width L1 of 20 nm and the space width S1 of 20 nm may be formed.

The etching of the silicon film 103 may be performed, as described later, by using plasma of gas including chlorine such as Cl₂, Cl₂+HBr, Cl₂+O₂, Cl₂+N₂, Cl₂+HCl, and HBr+Cl₂+SF6, or gas including other halogen gas such as CF₄+O₂ and SF₆.

Next, the target etching film etching process of Step S21 is performed. In Step S21, the target etching film 102 is etched by using the mask pattern 108 as a mask, and thus, a pattern 109 having a line portion of the line width L1 and the space width S1 is formed. Also, FIG. 2C(k) is a cross-sectional view showing the structure of the semiconductor substrate after the target etching film etching process is performed.

Next, the carbon film removing process of Step S22 is performed. In Step S22, ashing or wet washing using a solvent is performed, and thus, the carbon film 106 (the mask pattern 108) remaining on the upper portion of the pattern 109 is removed. Also, FIG. 2C(l) is a cross-sectional view showing the structure of the semiconductor substrate after the carbon film removing process is performed.

Next, a film-forming apparatus used in a method of manufacturing a semiconductor device including a method of forming a mask pattern according to an embodiment of the present invention will be described with reference to FIGS. 3 and 4.

FIGS. 3 and 4 are respectively a vertical sectional view and a horizontal sectional view schematically showing the structure of a film-forming apparatus used in the method of manufacturing a semiconductor device including a method of forming a mask pattern according to an embodiment of the present invention. Also, In FIG. 4, a heating apparatus is omitted.

As shown in FIGS. 3 and 4, a film-forming apparatus 80 includes a processing container 1 of a cylindrical shape having a top end and an open lower end. The processing container 1 is entirely formed of, for example, quartz. A top plate 2 is disposed and sealed on the top end of the processing container 1. Also, to the lower end opening of the processing container 1, a manifold 3 formed of stainless steel in a cylindrical shape is connected through a seal member 4 such as an O-ring.

The manifold 3 supports the lower end of the processing container 1. A wafer boat 5 formed of quartz and capable of holding a plurality of target processing objects, for example, 50-100 units of semiconductor wafers W, in a multiple layers, can be inserted into the processing container 1 from the bottom side of the manifold 3. The wafer boat 5 has three supports 6 (refer to FIG. 4) and the wafers W can be supported in grooves formed in the supports 6.

The wafer boat 5 is held on the table 8 via a thermos bottle formed of quartz. The table 8 is supported on a rotation shaft 10 that penetrates a cover 9 formed of, for example, stainless steel and opening/closing the lower end opening of the manifold 3.

For example, a magnetic fluid seal 11 is provided at a portion of the rotation shaft 10 where the rotation shaft 10 penetrates the cover 9, and thereby the rotation shaft 10 is sealed with airtightness and is rotatably supported. Also, a seal member 12 formed of, for example, an O-ring, is installed between a periphery portion of the cover 9 and the lower end portion of the manifold 3, thereby maintaining sealing of the processing container 1.

The rotation shaft 10 is attached at the front end of an arm 13 that is supported by an elevation mechanism (not shown), such as a boat elevator, and elevates the wafer boat 5 and the cover 9 together so that the wafer boat 5 and the cover 9 may be inserted in or separated from the processing container 1. Also, the table 8 may be fixedly provided to the cover 9 to perform processing of the wafers W without rotating the wafer boat 5.

Also, the film-forming apparatus 80 includes a first gas supply mechanism 14, a second gas supply mechanism 15, and a third gas supply mechanism 16.

The first gas supply mechanism 14 includes an oxygen containing gas supply pipe 17 for supplying oxygen containing gas, for example, O₂ gas, into the processing container 1, a nitrogen containing gas supply pipe 18 for supplying nitrogen containing gas, for example, NH₃ gas, into the processing container 1, a carbon source gas supply pipe 19 for supplying carbon source gas, and a purge gas supply pipe 20 for supplying inactive gas for pipe purge, for example, N₂ gas.

An oxygen containing gas supply source 17a is connected to the oxygen containing gas supply pipe 17, and a flow controller 17b, such as a mass flow controller, and an opening/closing valve 17c are provided in the middle of the pipe 17. A nitrogen containing gas supply source 18a is connected to the nitrogen containing gas supply pipe 18, and a flow controller 18b and an opening/closing valve 18c are provided in the middle of the pipe 18. A carbon source gas supply source 19a is connected to the carbon source gas supply pipe 19, and a flow controller 19b and an opening/closing valve 19c are provided in the middle of the pipe 19. A purge gas supply source 20a is connected to the purge gas supply pipe 20, and a flow controller 20b and an opening/closing valve 20c are provided in the middle of the pipe 20. The oxygen containing gas supply pipe 17, the nitrogen containing gas supply pipe 18, the carbon source gas supply pipe 19, and the purge gas supply pipe 20 are connected to a gas dispersion nozzle 21 that is formed of a quartz pipe inwardly penetrating a side wall of the manifold 3, upwardly bent, and vertically extending. A plurality of gas jet holes 21a are formed at a predetermined interval in a vertical portion of the gas dispersion nozzle 21, and thus, gas can be ejected almost uniformly toward the processing container 1 in a horizontal direction from the respective gas jet holes 21a.

The second gas supply mechanism 15 includes a Si source gas supply pipe 22 for supplying a Si source gas to the inside of the processing container 1. A Si source gas supply source 22a is connected to the Si source gas supply pipe 22, and a flow controller 22b and an opening/closing valve 22c are provided in the middle of the pipe 22. The Si source gas supply pipe 22 is connected to a gas dispersion nozzle 24 that is formed of a quartz pipe inwardly penetrating the side wall of the manifold 3, upwardly bent, and vertically extending. Here, two gas dispersion nozzles 24 are provided (refer to FIG. 4). A plurality of gas jet holes 24a are formed at a predetermined interval along a lengthwise direction of each of the gas dispersion nozzles 24, and thus, gas can be ejected almost uniformly toward the processing container 1 in a horizontal direction from the respective gas jet holes 24a. Also, only one gas dispersion nozzle 24 may be provided.

Also, a processing gas supply pipe 27 for supplying removal gas for removing a silicon film to the inside of the processing container 1 as the process gas, may be provided at the second gas supply mechanism 15. A process gas supply source 27a is connected to the process gas supply pipe 27, and a flow controller 27b and an opening/closing valve 27c are provided in the middle of the pipe 27. The process gas supply pipe 27 is connected to the gas dispersion nozzles 24 that is formed of a quartz pipe inwardly penetrating the side wall of the manifold 3, upwardly bent, and vertically extending.

The third gas supply mechanism 16 includes a purge gas supply pipe 25 for supplying purge gas to the inside of the processing container 1. A purge gas supply source 25a is connected to the purge gas supply pipe 25, and a flow controller 25b and an opening/closing valve 25c are provided in the middle of the pipe 25. Also, the purge gas supply pipe 25 is connected to the purge gas nozzle 26 that penetrates the side wall of the manifold 3.

A plasma generation mechanism 30 for generating plasma of the supplied gas is installed at a part of the side wall of the processing container 1. The plasma generation mechanism 30 includes a plasma partition wall 32 closely welded to an outer wall of the processing container 1 to cover, from the outside, an opening 31 that is formed to be vertically narrow and lengthy by cutting off the side wall of the processing container 1 in a vertical direction with a predetermined width. The plasma partition wall 32 is formed to be vertically narrow and lengthy with a section of a concave shape and is formed of, for example, quartz. Also, the plasma generation mechanism 30 includes a pair of plasma electrodes 33 that are narrow and lengthy and arranged to face each other along the vertical direction on the outer surfaces of both walls of the plasma partition wall 32, and a high frequency power source 35 connected to the plasma electrodes 33 via a power supply line 34 and supplying high frequency electric power. As the high frequency power source 35 supplies a high frequency voltage of, for example, 13.56 MHz, to the plasma electrodes 33, plasma of oxygen containing gas may be generated. Also, the frequency of the high frequency voltage is not limited to 13.56 MHz and other frequency such as 400 kHz may be used therefor.

By providing the plasma partition wall 32 as above, a part of the side wall of the processing container 1 is indented outwardly in a concave shape, and thus, the inner space of the plasma partition wall 32 is integrally communicated to the inner space of the processing container 1 in a body. Also, the opening 31 is formed to be sufficiently long in the vertical direction to cover all the wafers W supported on the wafer boat 5 in a height direction.

The gas dispersion nozzle 21 that ejects the oxygen containing gas is bent outwardly in the radial direction of the processing container 1 in the middle of extending upwardly in the processing container 1, and then erected upwardly along the innermost portion in the plasma partition wall 32 (the farthest portion from the center of the processing container 1). Thus, when the high frequency power source 35 is turned on and thus a high frequency electric field is generated between the electrodes 33, the oxygen gas ejected from the gas jet holes 21a of the gas dispersion nozzle 21 is plasmarized and flows toward the center of the processing container 1 by being diffused.

An insulation protection cover 36 formed of, for example, quartz, is attached to the outer side of the plasma partition wall 32 to cover the plasma partition wall 32. Also, a coolant path that is not shown is formed in the internal portion of the insulation protection cover 36 so that the plasma electrodes 33 can be cooled by flowing, for example, cool nitrogen gas, therein.

The two gas dispersion nozzles 24 are installed at positions with the opening 31 interposed therebetween on the inner wall of the processing container 1. Aminosilane gas having one or two amino groups in one molecule as the Si source gas may be ejected in a direction toward the center of the processing container 1 from the gas jet holes 24a of the gas dispersion nozzles 24.

An exhaustion hole 37 for vacuum-exhausting the inside of the processing container 1 is formed at the opposite portion of the opening 31 of the processing container 1. The exhaustion hole 37 is formed to be long and narrow by cutting off the side wall of the processing container 1 in a vertical direction. An exhaustion cover member 38 formed to have a section of a concave shape to cover the exhaustion hole 37 is attached, by welding, to a portion corresponding to the exhaustion hole 37 of the processing container 1. The exhaustion cover member 38 extends upwardly along the side wall of the processing container 1 and defines a gas exit 39 in the upper portion of the processing container 1. A vacuum-exhaustion mechanism including a vacuum pump, which is not shown, performs vacuum-suction from the gas exit 39. A heating apparatus 40 of a case shape to heat the processing container 1 and the wafers W therein is provided to surround the outer periphery of the processing container 1.

The control of the respective constituent portions of the film-forming apparatus 80, for example, the supply/cutoff of each gas due to the opening/closing of the opening/closing value, the control of the gas flow by the flow controller, the on/off control of the high frequency power source 35, and the control of the heating apparatus 40, are performed by a controller 50 that is constituted of, for example, a microprocessor (computer). A user interface 51 including a keyboard for input operation of commands for an operation manager to manage the film-forming apparatus or a display for displaying operating state of the film-forming apparatus 80 by visualizing the same is connected to the controller 50.

Also, a memory unit 52 for storing a control program to implement various processes executed in the film-forming apparatus 80 under the control of the controller 50, or a program, that is, a recipe, to execute a process in each constituent portion of the film-forming apparatus 80 according to a process condition, is connected to the controller 50. The recipe is memorized in a central memory medium in the memory unit 52. The memory medium may be a hard disk or a semiconductor memory, or a portable one such as a CD-ROM, a DVD, or a flash memory. Also, the recipe may be appropriately transmitted from other device via a dedicated line, for example.

As necessary, by calling a certain recipe from the memory unit 52 by an instruction from the user interface 51 to be executed by the controller 50, under the control of the controller 50, a desired process is performed in the film-forming apparatus 80.

Next, the SiN forming process (deposition process) and the amorphous carbon film forming process according to the present embodiment which is performed by using the film-forming apparatus 80 configured as above will be described below.

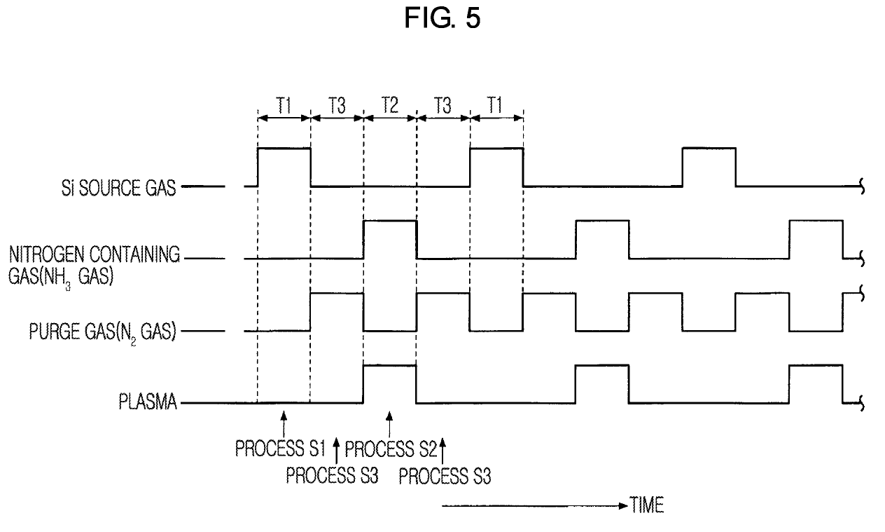

First, referring to FIG. 5, the forming process (deposition process) of a SiN film using the film-forming apparatus 80 is described. FIG. 5 is a timing chart showing the timing of a gas supply when a target etching film is formed, and explaining a method of forming a mask pattern according to an embodiment of the present invention.

In the film formation of a SiN, while silicon source gas is introduced in the processing container 1 by using the second gas supply mechanism 15, oxygen containing gas or nitrogen containing gas is introduced by the first gas supply mechanism 14, thereby forming a SiN film.

As the silicon source, organic based silicon, for example, ethoxysilane gas or aminosilane gas, may be used. The ethoxysilane may be, for example, TEOS (tetraethoxysilane). The aminosilane may be, for example, TDMAS (tris(dimethylamino)silane), BTBAS (bis(tertialbutylamino)silane), BDMAS (bis(dimethylamino)silane), BDEAS (bis(diethylamino)silane), DMAS (dimethylaminosilane), DEAS (diethylaminosilane), DPAS (dipropylaminosilane), or BAS (butylaminosilane).

Also, the nitrogen containing gas is supplied from the first gas supply mechanism 14 to the inner space of the plasma generation mechanism 30, the nitrogen containing gas is excited and plasmarized therein, and the silicon source gas is nitridizied by the nitrogen containing plasma so that a SiN film is formed.

The SiN film may be formed by simultaneously supplying the Si source gas and the nitrogen containing gas. However, in view of lowering a film-forming temperature, as shown in FIG. 5, a MLD (Molecular Layered Deposition) method may be preferably employed in which a process S1 for adsorbing the Si source gas by flowing the Si source gas and a process S2 for nitridizing the Si source gas by supplying the nitrogen containing gas to the processing container 1 are alternately repeated and a process S3 for purging gas remaining in the processing container 1 from the processing container 1 is performed therebetween.

In detail, in the process S1, as described above, the Si source gas is supplied to the processing container 1, for a period T1, from the gas jet holes 24a through the Si source gas supply pipe 22 and the gas dispersion nozzle 24 of the second gas supply mechanism 15, and thus, the Si source is adsorbed on the semiconductor wafer W (semiconductor substrate 101). The condition at this moment is based on the condition of the process S1 when the SiN film is formed. That is, the period T1 is, for example, 1-300 sec. Also, the pressure of the processing container 1 is, for example, 1.33-3990 Pa. The flow of the Si source gas is, for example, 1-5000 mL/min (sccm).

In the process S2 of supplying a nitrogen containing gas, the nitrogen containing gas, for example, NH₃ gas, is ejected from the gas jet holes 21a through the nitrogen containing gas supply pipe 18 and the gas dispersion nozzle 21 of the first gas supply mechanism 14. At this time, a high frequency electric field is generated by turning on the high frequency power source 35 of the plasma generation mechanism 30. The nitrogen containing gas, for example, NH₃ gas, is plasmarized by the high frequency electric field. The plasmarized nitrogen containing gas is supplied to the inside of the processing container 1. Accordingly, the Si gas adsorbed on the semiconductor wafer W (semiconductor substrate 101) is nitridized so that SiN is formed. A processing period T2 is, for example, 1-300 sec. Also, the pressure of the processing container 1 is, for example, 1.33-3990 Pa. The flow of the nitrogen containing gas is, for example, 100-10000 mL/min (sccm), which may vary according to the mounting number of the semiconductor wafers W. Also, the frequency of the high frequency power source 35 is, for example, 13.56 MHz. The power of, for example, 10-1000 W is employed.

Also, the process S3 performed between the processes S1 and S2 is a process of generating a desired reaction in the next process by removing the gas remaining in the processing container 1 after the process S1 or the process S2. This process is performed by supplying inactive gas, for example, N₂ gas, as the purge gas, from the purge gas supply source 25a of the third gas supply mechanism 16 through the purge gas supply pipe 25 and the purge gas nozzle 26 while vacuum-exhausting the inside of the processing container 1. A processing period T3 of the process S3 is, for example, 1-60 sec. Also, the flow of the purge gas is, for example, 0.1-5000 mL/min (sccm). Also, in the process S3, when the gas remaining in the inside of the processing container 1 can be removed, the vacuum-suction may be continuously performed without supplying the purge gas in a state in which supply of all gases are stopped. However, by supplying the purge gas, the remaining gas of the processing container 1 can be removed in a short time. Also, the pressure of the processing container 1 is, for example, 0.133-665 Pa.

By the above MLD method, the SiN film may be formed at a low temperature of 300° C. or less, and the film-formation is possible at an extremely low temperature of 100° C. or less by optimizing the conditions.

The SiN film may be formed by simultaneously supplying the Si source gas and the nitrogen containing gas. In this case, the pressure of the processing container 1 is, for example, about 7-1343 Pa, the flow of the Si source gas is, for example, about 1-2000 mL/min (sccm), the flow of the nitrogen containing gas is, for example, about 5-5000 mL/min (sccm). However, the film-forming temperature in this case requires a relatively high temperature of about 400-800° C.

Next, the film-forming method of an amorphous carbon film using the film-forming apparatus 80 will be described below.

In the film-forming process of an amorphous carbon film, a predetermined carbon source gas is introduced from the carbon source gas supply source 19a into the processing container 1 through the carbon source gas supply pipe 19 and plasmarized by the plasma generation mechanism 30, and, by plasma CVD, an amorphous carbon film is formed on the target etching film 102 formed on the semiconductor substrate 101 (the same as the wafer W). At this time, N₂ gas as a dilution gas may be introduced into the processing container 1 through the purge gas supply pipe 25. The frequency and power of high frequency electric power in the plasma generation mechanism 30 may be appropriately set according to a required reactivity. Since the plasmarized gas has a high reactivity, it is possible to lower the film-forming temperature. Also, since the plasma generation is not necessary, when the reactivity is sufficient, film-forming by thermal CVD may be available.

As the carbon source gas (material gas), one that can film-form carbon through reaction is acceptable and typically a process gas including carbon hydrogen gas is used. As the carbon hydrogen gas, ethylene (C₂H₄), methane (CH₄), ethane (C₂H₆), acetylene (C₂H₂), or butyne (C₄H₆) may be used. As gas other than carbon hydrogen gas, inactive gas such as Ar gas or hydrogen gas may be used.

The pressure of a chamber when the amorphous carbon film is formed is preferably 6667-666665 Pa. Also, the substrate temperature when the amorphous carbon film is formed is preferably 800° C. or less, more preferably, 600-700° C.

Next, the silicon film removing process according to the present embodiment by using the film-forming apparatus 80 will be described below. That is, in the present embodiment, the silicon film removing process may be performed within the film-forming apparatus performing a film-forming process. As the silicon film removing process is performed within the film-forming apparatus performing a film-forming process, the processing apparatus used for the silicon film removing process does not need to be separately prepared and also the size and cost of the overall semiconductor manufacturing apparatus can be reduced.

First, the inside of the processing container 1 is set to be a predetermined temperature, for example, 300° C. Also, after a predetermined amount of nitrogen is supplied to the inside of the processing container 1 from the purge gas supply pipe 25, the wafer boat 5 accommodating the semiconductor substrate 101 on which the carbon film is etched back is placed on the cover 9, and then, the cover 9 is ascended by an elevation mechanism that is not shown to load the wafer boat 5 in the processing container 1.

Next, with supplying a predetermined amount of nitrogen to the inside of the processing container 1 from the purge gas supply pipe 25, the inside of the processing container 1 is set to a predetermined temperature. The temperature of the inside of the processing container 1 is preferably set to a temperature at which chlorine (Cl₂) as the removal gas supplied to the inside of the processing container 1 in the below-described removal process is activated, for example, 350° C. or higher. Thus, the temperature of the inside of the processing container 1 is preferably set to 350-500° C. However, even when the temperature of the inside of the processing container 1 is lower than 350° C., since the chlorine can be activated by a method other than the heat in the processing container 1, the temperature of the inside of the processing container 1 may be set to be lower than 350° C.

Also, the gas in the processing container 1 is exhausted and the processing container 1 is depressurized to a predetermined pressure, for example, 1330 Pa (10 Torr). The temperature and pressure of the inside of the processing container 1 is adjusted until the inside of the processing container 1 is stabilized at predetermined pressure and temperature.

When the inside of the processing container 1 is stabilized at predetermined pressure and temperature, with stopping the supply of nitrogen from the purge gas supply pipe 25, the removal gas of gas including chlorine is introduced into the processing container 1 from the processing gas supply pipe 27. In the present embodiment, the removal gas formed of a predetermined amount, for example, 0.25 L/min, of chlorine and a predetermined amount, for example, 3 L/min, of nitrogen as dilution gas, is introduced into the processing container 1.

The removal gas introduced into the processing container 1 is heated within the processing container 1, and thus, the chlorine included in the removal gas is activated. The activated chlorine etches the amorphous silicon film.

Here, since the activated chlorine is used for the removal of the amorphous silicon film, the quartz is hardly etched. As a result, a member such as the processing container 1 is not etched in the removal process. Also, the generation of rust in the member such as the processing container 1 due to water may be prevented.

In the removal process, the pressure of the processing container 1 is preferably 133 Pa-26.6 kPa (1 Torr-200 Torr), the flow of chlorine is preferably 0.05 L/min-1 L/min, and the flow of nitrogen is preferably 0.6 L/min-3 L/min. Also, the flow ratio of chlorine and nitrogen is preferably 1:1-1:12.

When the silicon film removal process is completed, a predetermined nitrogen is supplied to the inside of the processing container 1 from the purge gas supply pipe 25 and the pressure of the processing container 1 is returned to the atmospheric pressure. Finally, as the cover 9 is descended by the elevation mechanism that is not shown, the wafer boat 5 is unloaded.

Also, in the present embodiment, although the process gas including chlorine is supplied to the inside of the processing container 1 that is heated to a temperature at which the chlorine can be activated so that the chlorine in the process gas is activated, gas including activated chlorine may be supplied to the inside of the processing container 1, by providing an activation means in the processing gas introduction pipe. In this case, even when the temperature of the inside of the processing container 1 in the removal process is set to be low, the activated chlorine can be supplied to the semiconductor wafers W, and thereby the removal process can be performed at a low temperature. The activation means may be a plasma generation means, an ultraviolet ray generation means, or a catalyst activation means.

Also, in the present embodiment, although it is described that a mixed gas of chlorine and nitrogen is used as the process gas, gas including chlorine may suffice. Also, although it is described that nitrogen gas is included as the dilution gas, the dilution gas may not be included. However, since the setting of a processing time is made easy by including the dilution gas, it is preferable to include the dilution gas. The dilution gas is preferably inactive gas and may be, for example, helium (He) gas, neon (Ne) gas, or argon (Ar) gas, in addition to the nitrogen gas.

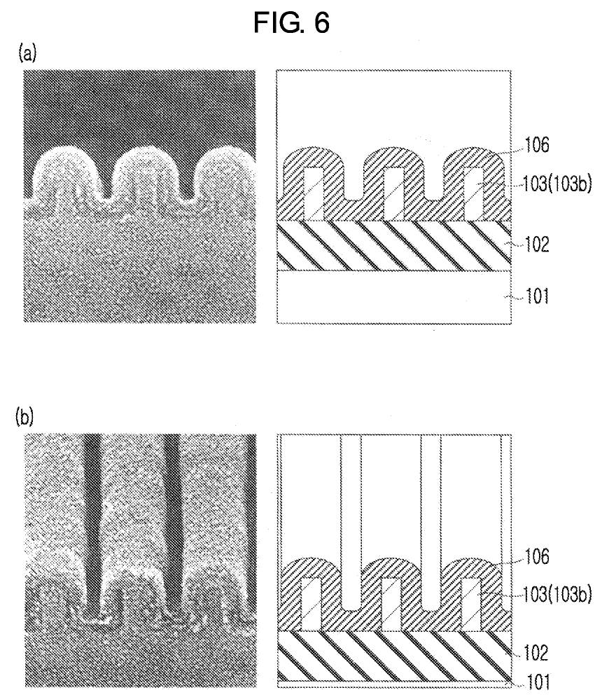

Next, referring to FIGS. 6-9, effects of improving symmetricity of the shape of the side wall portion and enhancing processing precision of the etching process of a target etching film according to the present embodiment will be described below. In the following description, an evaluation is performed by measuring the width dimension of each pattern after the semiconductor manufacturing method including the mask pattern forming method according to the present embodiment, and a result of the evaluation is described below.

In an embodiment, as shown in FIG. 1, the respective processes from the deposition process to the carbon film removing process, including the film-forming process, the etchback process, and the silicon film removing process, are performed. The conditions of the film-forming process, the etchback process, and the silicon film removing process in the present embodiment are shown below.

(A) Film-Forming Process

Material gas: ethylene (C₂H₄)

Temperature of substrate: 800° C.

Pressure of the inside of a film-forming apparatus: 50 Torr

Gas flow: 2000 sccm

Supply time: 923 sec

(B) Etchback Process

Etching gas: O₂ gas

Temperature of substrate: 30° C.

Pressure of the inside of a film-forming apparatus: 20 mTorr

Gas flow: 100 msccm

Frequency of a high frequency power source (upper electrode/lower electrode): 60/13 MHz

Power of a high frequency power source (upper electrode/lower electrode): 600/50 W

(C) Silicon Film Removing Process

Material gas: chlorine (Cl₂) gas

Temperature of substrate: 300° C.

Pressure of the inside of a film-forming apparatus: 40 Torr

Gas flow: 2000 sccm

Supply time: 5 hour

FIG. 6 shows images of a pattern photographed by using a SEM (Scanning Electron Microscope) after the (A) film-forming process is performed according to the present embodiment. FIGS. 6(a) and 6(b) are, respectively, images (left) of the section of a resist pattern photographed from the front side and obliquely above the resist pattern, and schematic views (right) for explaining the images. It can be found out that the carbon film 106 is formed to isotropically coat the surface of the silicon film pattern 103b of the silicon film 103.

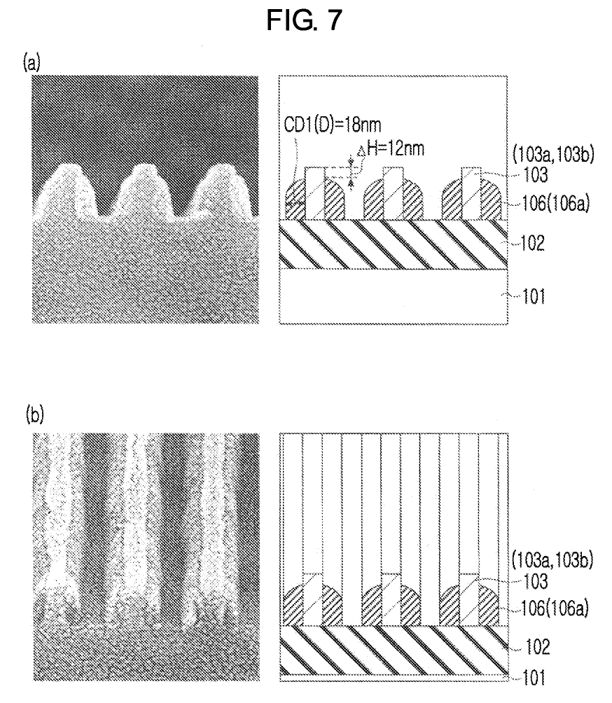

FIG. 7 shows images of a silicon film pattern photographed by using a SEM (Scanning Electron Microscope) after the (B) etchback process is performed according to the present embodiment. FIGS. 7(a) and 7(b) are, respectively, images (left) of the section of the silicon film pattern photographed from the front side and obliquely above the silicon film pattern, and schematic views (right) for explaining the images. The width dimension of the first line portion 103a of the silicon film pattern 103b is set to CD (the same as the D described in FIG. 2C(i)) and the height dimension (shoulder damage height dimension) of a portion protruding higher than the side wall portion 106a of the first line portion 103a is set to ΔH.

As shown in FIG. 7, as a result of performing the embodiment, the values of CD1(=D)=18 nm and ΔH=12 nm are obtained. Also, as shown in FIG. 7, the first line portion 103a formed of the silicon film 103 becomes narrower toward the end portion thereof so that the side wall portion 106a formed of the carbon film 106 is not shaped in an asymmetrical shape like a crab claw. Also, the shoulder damage shape is superior.

This is because the silicon film is chemically stable compared to the photoresist film and, in the film-forming process and the etchback process, the tip end of the first line portion 103a formed of the silicon film 103 is selectively etched so as not to become narrower toward the end portion thereof. Also, since the ratio (selection ratio) of etching rate of the carbon film 106 to the silicon film 103 is high, after the carbon film 106 is etched back and removed from the upper portion of the first line portion 103a, when the carbon film 106 is etched back again, the silicon film 103 is not etched and the shape of the silicon film 103 is maintained.

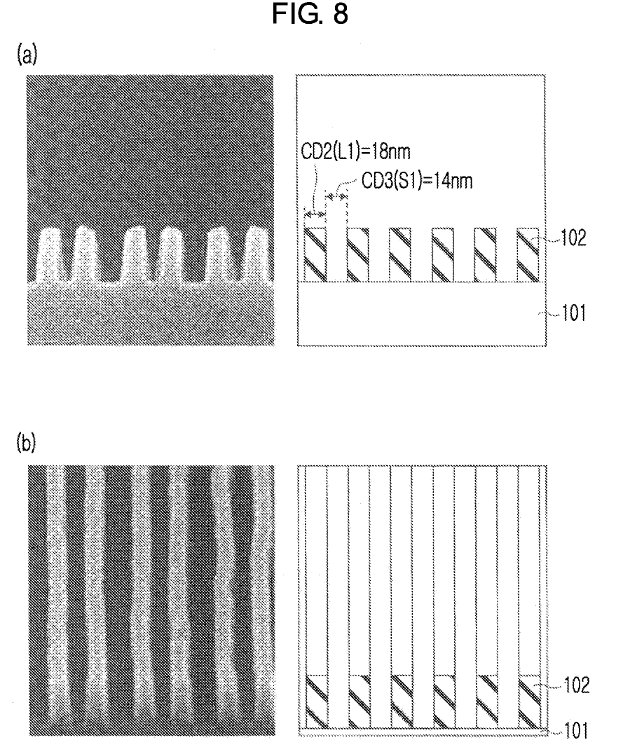

FIG. 8 shows images of a pattern photographed by using a SEM (Scanning Electron Microscope) after the (C) silicon film removing process is performed and additionally the target etching film etching process and the carbon film removing process are performed, according to the present embodiment. FIGS. 8(a) and 8(b) are, respectively, images (left) of the section of a pattern formed of the target etching film photographed from the front side and obliquely above the pattern, and schematic views (right) for explaining the images. The dimensions of the line width and the space width of the pattern 109 formed of the target etching film 102 are set to CD2 (the same as the L1 described in FIG. 2C(l)) and CD3 (the same as the S1 described in FIG. 2C(l)), respectively.

As shown in FIG. 8, as a result of performing the embodiment, the values of CD2(=L1)=18 nm and CD3(=S1)=14 nm are obtained. Also, as shown in FIG. 8, the pattern 109 formed of the target etching film 102 has almost the same CD2 to the tip end thereof and does not become narrower toward the end portion thereof, thereby having a superior sectional shape.

This is because the ratio (selection ratio) of etching rate of the target etching film (SiN film) 102 to the carbon film 106 is high and, as shown in FIG. 2C(k), in the target etching film etching process, the target etching film 102 can be etched while leaving the mask pattern 108 formed of the side wall portion 106a of the carbon film 106. Also, as the selection ratio of the carbon film 106 is increased, the film thickness of the carbon film 106 can be decreased.

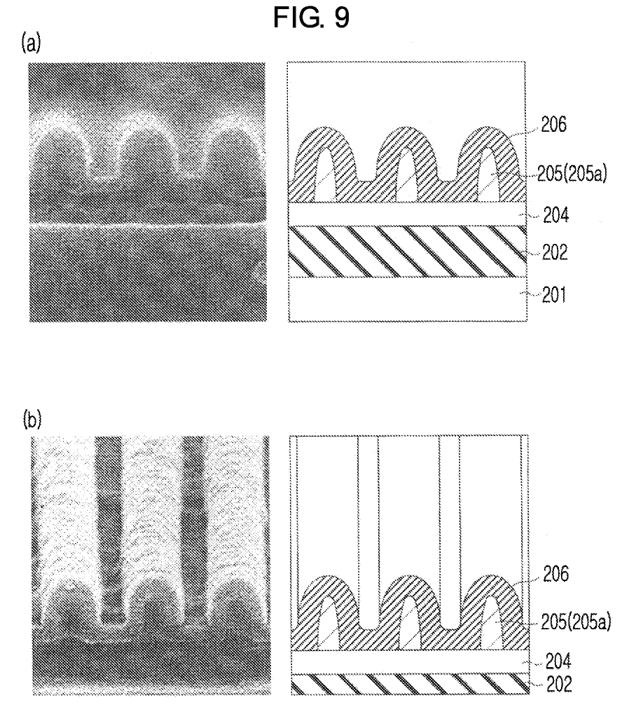

In the meantime, instead of the (A) film-forming process of the present embodiment, to isotropically coat the surface of the resist pattern, a comparative example for forming a silicon oxide film is performed. FIG. 9 shows images of a pattern after the silicon oxide film is formed in the comparative example, photographed by using a SEM (Scanning Electron Microscope). FIGS. 9(a) and 9(b) are, respectively, images (left) of the section of a resist pattern photographed from the front side and obliquely above the pattern, and schematic views (right) for explaining the images. In the comparative example, a target etching film 202 formed of a SiN film and a reflection prevention film 204 are sequentially deposited on a semiconductor substrate 201, a resist film 205 is formed thereon, and a silicon oxide film 206 is formed on a resist pattern 205a obtained by patterning the resist film 205.

In the comparative example, the tip end of the resist pattern 205a becomes narrower toward the end portion thereof, unlike the rectangular shape of the tip end of the silicon film pattern 103b in the present embodiment. Since the silicon oxide film 206 is formed such that the surface of the resist pattern 205a having the narrowed tip end can be isotropically coated, when the silicon oxide film 206 is etched back to remain as a side wall portion of the resist pattern 205a, the side wall portion becomes asymmetrical and a processing precision degree cannot be improved when etching the target etching film 202 under the side wall portion.

Thus, according to the method of forming a mask pattern and the method of manufacturing a semiconductor device according to the present embodiment, in the film-forming process and the etchback process, since the tip end of the first line portion formed of a silicon film does not become narrower toward the end portion thereof by being selectively etched, the symmetricity of the shape of the side wall portion may be improved. Also, the target etching film may be etched by using the carbon film having a high selection ratio with respect to the target etching film as the side wall portion.

Thus, the processing precision degree of etching of the target etching film may be improved.

As described above, according to the present invention, when the SWP is performed by forming a mask pattern, the symmetricity of the shape of the side wall portion may be improved, and the processing precision degree when etching the target etching film may be improved.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A method of forming a mask pattern, the method comprising:
a film-forming process which forms a carbon film, to isotropically coat a surface of a silicon film pattern in which a first line portion formed of a silicon film that is formed on a target etching film on a substrate is arranged;
an etchback process which etches back the carbon film such that the carbon film is removed from an upper portion of the first line portion and remains as a side wall portion of the first line portion; and
a silicon film removing process which forms a mask pattern in which the side wall portion is arranged, by removing the first line portion.

2. The method of claim 1, wherein the silicon film removing process is performed within a film-forming apparatus that performs the film-forming process.

3. The method of claim 1, wherein the carbon film comprises amorphous carbon.

4. The method of claim 1, wherein the silicon film comprises amorphous silicon.

5. The method of claim 1, wherein the target etching film comprises silicon nitride.

6. The method of claim 1, wherein, in the film-forming process, gas selected from ethylene, methane, ethane, acetylene, or butyne is used as a material gas.

7. The method of claim 1, wherein, in the silicon film removing process, chlorine containing gas is used.

8. The method of claim 1, wherein, in the etchback process, oxygen containing gas is used as a process gas.

9. The method of claim 1, further comprising:
an organic film pattern forming process which forms an organic film through a reflection prevention film on the silicon film and forms an organic film pattern, in which a second line portion is arranged, by patterning the organic film; and
a first pattern forming process which etches the reflection prevention film and the silicon film by using the organic film pattern and forms the silicon film pattern.

10. The method of claim 9, wherein the first pattern forming process comprises:
a trimming process which trims the organic film pattern;
a reflection prevention film etching process which etches the reflection prevention film using a trimmed organic film pattern as a mask and forms a reflection prevention film pattern formed of the reflection prevention film; and
a silicon film etching process which etches the silicon film using the reflection prevention film pattern as a mask and forms the silicon film pattern.

11. A method of manufacturing a semiconductor device having a target etching film pattern forming process which forms a pattern formed of the target etching film, by using the mask pattern formed by performing the method of forming a mask pattern defined in claim 1.

12. The method of claim 11, wherein the target etching film pattern forming process comprises:
a target etching film etching process which etches the target etching film using the mask pattern as a mask; and
a carbon film removing process which removes the side wall portion.
